(19) United States
(12) Patent Application Publication
(10) Pub. No.: US 2026/0068376 A1
(43) Pub. Date: Mar. 5, 2026

(54) METHOD FOR ENCAPSULATION OF LED DISPLAY MODULES

(71) Applicant: O-Flex Co., Ltd., Daejeon (KR)

(72) Inventors: Hyunjee YOO, Daejeon (KR); Sera KIM, Daejeon (KR); Mooncheol SHIN, Daejeon (KR); Hyeona KIM, Daejeon (KR)

(21) Appl. No.: 19/311,259

(22) Filed: Aug. 27, 2025

(30) Foreign Application Priority Data
Sep. 5, 2024 (KR) 10-2024-0121121

(51) Int. Cl. H10H 29/01; H01L 25/075

(52) U.S. Cl. CPC H10H 29/0362

(57) ABSTRACT

Embodiments relate to a method of encapsulating an LED display module, where the method includes: placing a substrate, on which a multiple number of LEDs are mounted, in a chamber and forming a vacuum; dispensing a protective material such that the protective material embeds and surrounds the plurality of LEDs; breaking the vacuum formed in the chamber; flattening the dispensed protective material by placing a flattening board on the dispensed protective material and pressing; and curing the flattened protective material by irradiating UV rays onto the flattened protective material. An embodiment of the invention can suppress the occurrence of bubbles at the portions around the chip LEDs or package LEDs and at the interface between the protective layer and the PCB during the procedure for forming the protective layer for an LED display module.

### CROSS-REFERENCE TO RELATED APPLICATIONS

This application claims the benefit of Korean Patent Application No. 10-2024-0121121, filed with the Korean Intellectual Property Office on Sep. 5, 2024, the disclosure of which is incorporated herein by reference in its entirety.

### BACKGROUND

### 1. Technical Field

The invention relates to a method for the encapsulation of LED display modules, more particularly to an encapsulation process for an LED display module that can suppress the occurrence of bubbles at the portions around the chip LEDs or package LEDs and the interface between the protective layer and the PCB, during the procedure for forming a protective layer, and can form a flattened layer without requiring a separate procedure for this purpose.

### 2. Description of the Related Art

The LED display is a high-precision apparatus and necessarily requires a stable operation. However, with the decrease in size of LEDs and package LEDs, so also is the adhesion area between the LEDs and the printed circuit board (PCB) and/or solder decreasing, resulting in the problem that the LEDs may become easily detached when there is an external impact. Also, since LEDs are sensitive to heat and moisture, the LEDs may become degraded and have a shortened lifespan if used without suitable protection. A high durability for the display is of particular importance especially when the display is used under unfavorable conditions, as in the case of outdoor advertisement panels and mobile devices, which are exposed to the outdoor environment. Moreover, with the expansion of the digital signage market, conventional paper-based advertisements are being replaced by LED displays, and maintenance issues, for example related to the direct cleaning of the screen, etc., have created a greater demand for the encapsulation process of LED modules.

The technology for protecting the LEDs in an LED display is essential for ensuring the performance, lifespan, and reliability of the display, and as such, various research and development efforts are being focused on materials and techniques for protecting LEDs.

Conventional materials for protecting LEDs include thermosetting and room temperature setting types. Thermosetting types involve high curing temperatures and thus require high energy and also entail the problem that an additional lapping procedure is required for flattening, since differences in surface tension at positions where LEDs are and are not mounted make it difficult to provide a uniform thickness during the thermal curing procedure. Further, the lapping procedure may leave a white residue on the surfaces and may thus necessitate an additional optical film. Room temperature setting types, on the other hand, require a very long duration for the curing procedure and entail severe discoloration.

To overcome these problems, recent attempts have focused on applying UV curable protective materials. However, with these materials, bubbles may form at the portions around the chip LEDs or package LEDs and at the interface between the protective layer and the PCB. Such bubbles may not be easy to remove, and the bubbles may lead to separating or peeling between the PCB and the protective material or a detaching of the protective layer from the LEDs and solder resist, thus posing problems in durability and reliability. The bubbles may also be observable to the user, creating a defective appearance and causing degradations in the optic properties of the product.

Also, when functional fillers such as a flame retardant, an optical property modifier, etc., are added to the protective material to enable the use of the LED display in various environments, the increase in viscosity of the protective material can make it more likely for bubbles to appear.

After a conventional protective material (e.g., a molding liquid, etc.) is dispensed, the protective material may be flattened by placing a release film over the protective material by way of roll lamination and pressing with a glass material or by using a vacuum press with a release film. However, air gaps may appear between the glass and the release film during the curing of the protective material after the pressing procedure, or defects shaped as wrinkles and puddles may be formed due to asymmetry in the curing contractions during the curing of the resin. Such defects may translate directly to defects in the surface of the protective material (for instance, as spotted marks, etc.), as shown in FIGS. 1 to 3.

### SUMMARY OF THE INVENTION

An aspect of the invention, which was conceived to resolve the problem described above, is to provide a method of encapsulating an LED display module that can suppress the occurrence of bubbles at the portions around the chip LEDs or package LEDs and at the interface between the protective layer and the PCB during the procedure for forming the protective layer.

Another aspect of the invention is to provide a method of encapsulating an LED display module that can suppress the occurrence of bubbles in the protective material even when a functional filler such as a flame retardant, etc., is added to the protective material.

Another aspect of the invention is to provide a method of encapsulating an LED display module that can suppress the occurrence of defects in the surface of the protective material during the procedure of curing the protective material and can enable an easier flattening process.

Another aspect of the invention is to provide a method of encapsulating an LED display module that can optimize the thickness adjustment and flattening procedures so as to minimize height discrepancies in the assembly of the LED display module.

Other objectives of the invention will be more clearly understood from the embodiments set forth below.

One aspect of the invention provides a method of encapsulating an LED display module, where the method includes: placing a substrate, on which a multiple number of LEDs are mounted, in a chamber and forming a vacuum; dispensing a protective material such that the protective material embeds and surrounds the plurality of LEDs; breaking the vacuum formed in the chamber; flattening the dispensed protective material by placing a flattening board on the dispensed protective material and pressing; and curing the flattened protective material by irradiating UV rays onto the flattened protective material.

Here, the forming of the vacuum can include: exhausting air from the chamber; and adjusting a pressure of the vacuum by using an inert gas.

The pressure in the chamber can be between 0.05 and 700 Torr as the vacuum is formed in the chamber.

More preferably, the pressure in the chamber can be between 0.05 and 600 Torr as the vacuum is formed in the chamber.

Here, O2 and moisture can be removed and an inert gas can remain in the chamber as the vacuum is formed in the chamber.

The pressure within the chamber can reach atmospheric pressure as the vacuum in the chamber is broken.

The flattening board can include any one of: (i) a glass board having an inorganic deposition or organic coating made to have a releasing property, (ii) a combination of a releasing glass having a releasing property and a pressing glass having a thickness greater than that of the releasing glass, and (iii) a glass board having a release film attached thereto.

Here, the protective material can contain at least one of a flame retardant and an optical property modifier.

The method of encapsulating an LED display module can further include, after the curing of the flattened protective material: removing the flattening board; baking the protective material to remove UV monomers remaining in the protective material; and cutting an edge portion of the protective material.

An AGLR film and/or a black OCA can be positioned on a surface of the flattened protective material.

An embodiment of the invention can suppress the occurrence of bubbles at the portions around the chip LEDs or package LEDs and at the interface between the protective layer and the PCB during the procedure for forming the protective layer for an LED display module.

Also, an embodiment of the invention can suppress the occurrence of bubbles in the protective material even when a functional filler such as a flame retardant, etc., is added to the protective material for the LED display module.

Also, an embodiment of the invention can suppress the occurrence of defects in the surface of the protective material during the procedure of curing the protective material for the LED display module and can enable an easier flattening process.

Also, an embodiment of the invention can optimize the thickness adjustment and flattening procedures so as to minimize height discrepancies in the assembly of the LED display module.

### BRIEF DESCRIPTION OF THE DRAWINGS

FIG. 1 illustrates a method of encapsulating an LED display module according to the related art.

FIG. 2 is a photograph of an LED display manufactured according to the method shown in FIG. 1 wherein a defect has occurred in the exterior.

FIG. 3 is a photograph showing bubbles that have formed in portions around the LEDs during the forming of a molding by way of dispensing under an atmosphere according to the related art.

FIG. 4 illustrates a method of encapsulating an LED display module according to an embodiment of the invention.

FIG. 5 is a photograph of an LED display manufactured according to the method shown in FIG. 4 wherein no defect has occurred in the exterior.

FIG. 6 is a photograph showing a molding with controlled bubbles formed according to a method of encapsulating an LED display module according to an embodiment of the invention.

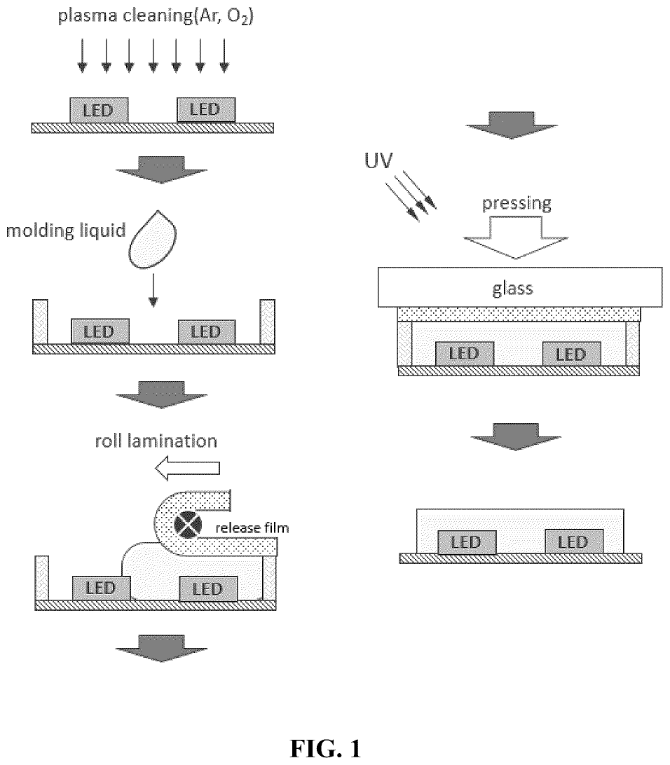

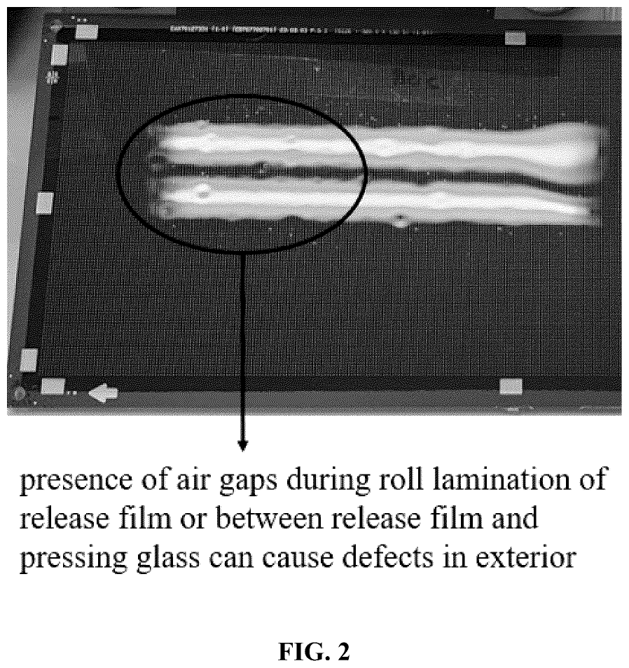

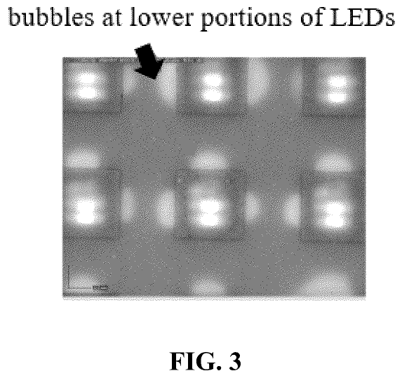

### DETAILED DESCRIPTION OF THE INVENTION

As the invention allows for various changes and numerous embodiments, particular embodiments will be illustrated in the drawings and described in detail in the written description. However, this is not intended to limit the invention to particular modes of practice, and it is to be appreciated that all changes, equivalents, and substitutes that do not depart from the spirit and technical scope of the invention are encompassed by the invention. In the description of the invention, certain detailed explanations of the related art are omitted if it is deemed that they may unnecessarily obscure the essence of the invention.

While such terms as “first” and “second,” etc., can be used to describe various components, such components are not to be limited by the above terms. The above terms are used only to distinguish one component from another.

The terms used in the present specification are merely used to describe particular embodiments and are not intended to limit the invention. An expression used in the singular encompasses the expression of the plural, unless it has a clearly different meaning in the context.

In the present specification, it is to be understood that terms such as “including” or “having,” etc., are intended to indicate the existence of the features, numbers, steps, actions, components, parts, or combinations thereof disclosed in the specification and are not intended to preclude the possibility that one or more other features, numbers, steps, actions, components, parts, or combinations thereof may exist or may be added. Certain embodiments of the invention will be described below in more detail with reference to the accompanying drawings.

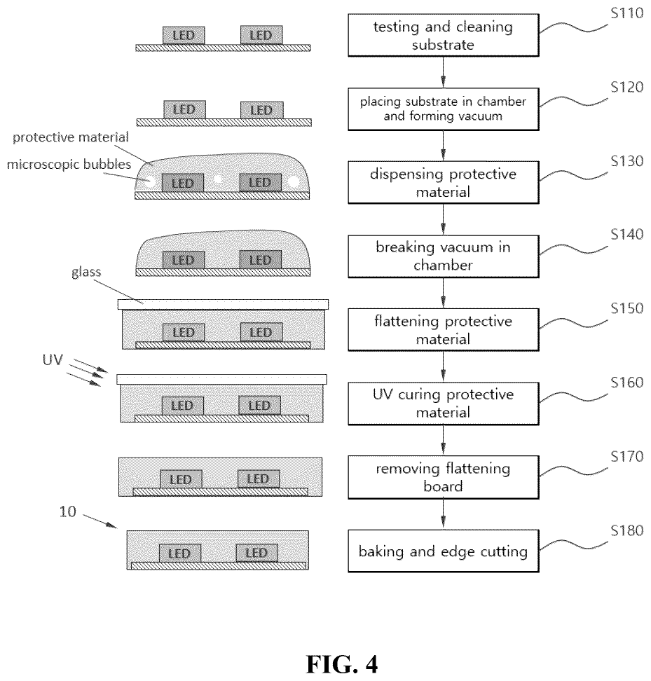

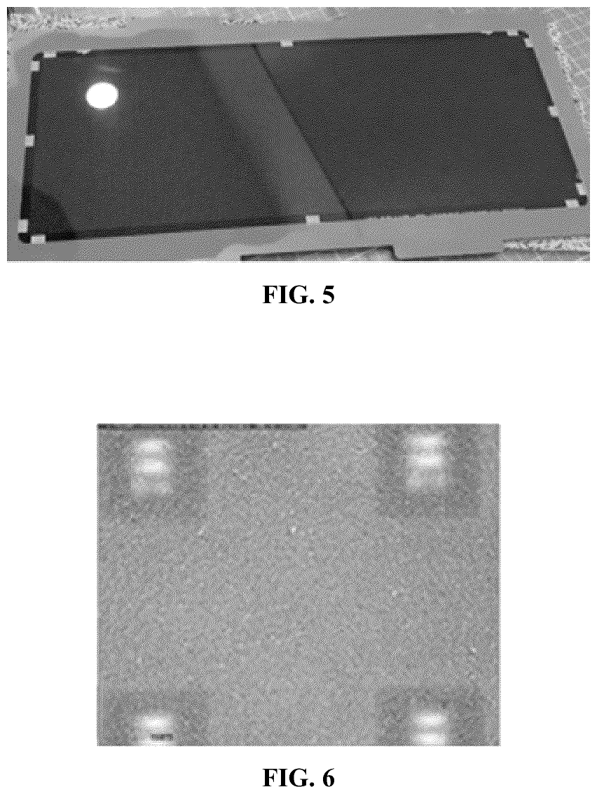

FIG. 4 illustrates a method of encapsulating an LED display module according to an embodiment of the invention, FIG. 5 is a photograph of an LED display manufactured according to the method shown in FIG. 4 wherein no defect has occurred in the exterior, and FIG. 6 is a photograph showing a molding with controlled bubbles formed according to a method of encapsulating an LED display module according to an embodiment of the invention.

As illustrated in FIG. 4, a method of encapsulating an LED display module according to an embodiment of the invention can include testing and cleaning the substrate (S110), placing the substrate in a chamber and forming a vacuum (S120), dispensing a protective material (S130), breaking the vacuum in the chamber (S140), flattening the protective material (S150), UV curing the protective material (S160), removing the flattening board (S170), and baking and edge cutting (S180).

The step for testing and cleaning the substrate (S110) can include testing the substrate (S110-1) and cleaning the substrate (S110-2) performed in order. A multiple number of LEDs may be mounted on the substrate.

In the substrate testing step (S110-1), a lighting test and a visual examination can be performed. The lighting test can include checking for unlighted points, abnormal lighting, uniform luminance, color difference, etc., with a lighting tool and a luminance meter. The visual examination can include checking whether or not there are smudges, broken lines, and damaged chips on the substrate.

In the substrate cleaning step (S110-2), the cleaning of the substrate can include plasma cleaning. The plasma cleaning gas can be Ar or O2, or another suitable gas can be selected according to the surface coating of the substrate. The power and speed of the plasma cleaning can also be chosen in consideration of the equipment dimensions and the cleaning state of the substrate.

The step for placing the substrate in a chamber and forming a vacuum (S120) can include placing the substrate, on which multiple LEDs are mounted, in a chamber and forming a vacuum. Here, the magnitude of the vacuum pressure in the chamber can be adjusted by using an inert gas that has been controlled for O2 and moisture content. For example, the step for forming a vacuum can include a step of exhausting the air within the chamber and a step of adjusting the pressure of the vacuum by using an inert gas. That is, after decreasing the pressure within the chamber to a preset pressure value or lower, an inert gas (N2, Ar, etc.) can be injected into the chamber to adjust the degree of vacuum within the chamber. As a vacuum is formed in the chamber, the pressure in the chamber can be 0.05 to 700 Torr, preferably 0.05 to 600 Torr. Also, as a vacuum is formed in the chamber, O2 and moisture may be removed, and only inert gas that does not inhibit UV reaction may remain in the chamber. Here, the content of O2 can be 300 ppm or lower. The inert gas can be N2, Ar, etc. The reason O2 should be removed is because O2 or O2 bubbles trapped in the dispensed protective material (molding liquid) may end radical reactions and thus inhibit the UV curing of the protective material.

The step for dispensing the protective material (S130) can include dispensing the protective material such that the protective material embeds and surrounds the multiple LEDs. The protective material can be a UV curable resin. The viscosity of the protective material can be 200 to 10,000 cps. After the protective material is dispensed, the temperature of the stage can be maintained at 50±10° C. to increase the spreadability of the protective material.

In step of breaking the vacuum in the chamber (S140), the vacuum may be broken, and atmospheric pressure may be provided in the chamber. Here, providing the atmospheric pressure can remove microscopic bubbles or vacuum cavities that might have formed within the dispensed protective material. That is, the pressure difference can cause the microscopic bubbles to contract, and the bubbles may be filled in.

The step for flattening the protective material (S150) can include flattening the dispensed protective material by placing a flattening board on top of the dispensed protective material and pressing. Here, the flattening board can be a glass board having a releasing property. More specifically, the flattening board can be (i) a glass board having an inorganic deposition or organic coating made to have a releasing property and can preferably be an inorganically deposited glass board for better reuse. Alternatively, the flattening board can be (ii) composed of a glass having a releasing property and a pressing glass that is thicker than the releasing glass. Here, the glass having the releasing property can have a thickness of 0.5 to 2 mm, while the pressing glass can be 10 to 50 mm. Alternatively, the flattening board can be a glass board to which a release film has been attached. The flattening material can have a larger size than the substrate so as to perform the pressing; for example, the flattening material can have a size of +10 mm compared to the substrate. Also, the pressure applied during the pressing can be adjusted depending on the thickness of the molding layer being formed and the quality of the exterior. An embodiment of the invention does not use a separate release film and therefore can prevent defects that would otherwise occur in the surface of the protective material according to the related art, for example due to air gaps forming between the glass and the release film and curing wrinkles forming in the release film.

The step for UV curing the protective material (S160) is for curing the flattened protective material by irradiating UV rays. The UV curing step can be performed multiple times and can be performed under different conditions each time. For example, if the UV curing is performed in three rounds, a first round of UV curing can be performed to minimize curing contraction, after which the second and third rounds of curing can be performed on uncured areas. The viscosity of the protective material can be 100 cps to 10000 cps. The protective material can include at least one of a flame retardant, an optical property modifier, inorganic scattering particles, organic scattering particles, light-absorbing particles, and transmissivity control particles. Here, if the protective material includes a flame retardant, the completed micro- or package LED display would have a flame retardant property and thus would be applicable to a large indoor-use signage display. Also, if the protective material includes scattering particles, the light emitted to the exterior by the LEDs can be diffused by the scattering particles. Also, it would be possible to adjust the intensity of the light emitted to the exterior by the LEDs by adjusting the amount of transmissivity control particles included in the protective material. The protective material can have a Young's modulus of 10 to 1000 MPa. Here, a Young's modulus higher than 1000 MPa for the protective material can degrade cause cracking and breaking during the cutting and processing of the molding layer 500, whereas a Young's modulus lower than 10 MPa can degrade the molding layer's function of protecting the LEDs, can be susceptible to scratches, furrows, etc., in the exterior, and can allow foreign substances to easily adhere to the surface.

The step for removing the flattening board (S170) is for removing the flattening board that was used for pressing the dispensed protective material. A separate removal device can be used for removing the flattening board. As described above, the flattening board can have an inorganic deposition or organic coating having a releasing property, can include a release glass, or can be a glass board to which a release film is attached. Thus, the flattening board may not be strongly attached to the protective material, so that the flattening board may be easily removed, and the removal of the flattening board may not leave defects on the surface of the protective material.

The step for baking and edge cutting (S180) can include a baking step (S180-1) and an edge cutting step (S180-2) performed in order.

The baking step (S180-1) is for removing organic substances of low molecular weight remaining in the protective material. The baking step (S180-1) can be performed under an 02 atmosphere in an oven with the temperature set to 100 to 150° C. for 30 to 120 minutes. The baking step can also be performed in a vacuum oven.

The edge cutting step (S180-2) is for cutting off the edge portions of the protective material. A dicing apparatus can be used for the edge cutting.

An AGLR (anti-glare & low reflection) film and/or a black OCA (optically clear adhesive) can be additionally positioned on the surface of the flattened protective material.

Finally, a completion check step can be performed to finish the manufacturing process of the micro-LED display.

The preferred embodiments of the invention provided above are disclosed for illustrative purposes only. It should be appreciated that the skilled person having ordinary skill in regard to the invention would be able to make various modifications, alterations, and additions without departing from the spirit and scope of the invention and that such modifications, alterations, and additions are encompassed within the scope of claims below.

What is claimed is:

1. A method of encapsulating an LED display module, the method comprising:
placing a substrate in a chamber and forming a vacuum, the substrate having a plurality of LEDs mounted thereon;
dispensing a protective material such that the protective material embeds and surrounds the plurality of LEDs;
breaking the vacuum formed in the chamber;
flattening the dispensed protective material by placing a flattening board on the dispensed protective material and pressing; and
curing the flattened protective material by irradiating UV rays onto the flattened protective material.

2. The method of encapsulating an LED display module according to claim 1, wherein the forming of the vacuum comprises:
exhausting air from the chamber; and
adjusting a pressure of the vacuum by using an inert gas.

3. The method of encapsulating an LED display module according to claim 1, wherein a pressure in the chamber is between 0.05 and 700 Torr as the vacuum is formed in the chamber.

4. The method of encapsulating an LED display module according to claim 3, wherein the pressure in the chamber is between 0.05 and 600 Torr as the vacuum is formed in the chamber.

5. The method of encapsulating an LED display module according to claim 1, wherein O2 and moisture are removed and an inert gas remains in the chamber as the vacuum is formed in the chamber.

6. The method of encapsulating an LED display module according to claim 1, wherein a pressure within the chamber reaches atmospheric pressure as the vacuum in the chamber is broken.

7. The method of encapsulating an LED display module according to claim 1, wherein the flattening board includes any one of:
(i) a glass board having an inorganic deposition or organic coating made to have a releasing property,
(ii) a combination of a releasing glass having a releasing property and a pressing glass having a thickness greater than that of the releasing glass, and
(iii) a glass board having a release film attached thereto.

8. The method of encapsulating an LED display module according to claim 1, wherein the protective material contains at least one of a flame retardant and an optical property modifier.

9. The method of encapsulating an LED display module according to claim 1, further comprising, after the curing of the flattened protective material:
removing the flattening board;
baking the protective material to remove UV monomers remaining in the protective material; and
cutting an edge portion of the protective material.

10. The method of encapsulating an LED display module according to claim 1, wherein an AGLR film and/or a black OCA are positioned on a surface of the flattened protective material.

11. An LED display assembled using an LED display module, the LED display module manufactured by the method of encapsulating an LED display module according to claim 1.
